(19) United States
(12) Patent Application Publication
(10) Pub. No.: US 2004/0084998 A1
(43) Pub. Date: May 6, 2004

(54) Control valve for liquids

(76) Inventor: Friedrich Boecking, Stuttgart (DE)

Correspondence Address: RONALD E. GREIGG, GREIGG & GREIGG P.L.L.C., 1423 POWHATAN STREET, UNIT ONE, ALEXANDRIA, VA, 22314, US

(21) Appl. No.: 10/332,746

(22) PCT Filed: May 10, 2002
(86) PCT No.: PCT/DE02/01702

(30) Foreign Application Priority Data
May 12, 2001 (DE) 101 23 172.5

(51) Int. Cl. H01L 41/08

(52) U.S. Cl. 310/328

(57) ABSTRACT

The present invention relates to a valve for controlling fluids, having a piezoelectric actuator (2), a booster for boosting the stroke of the piezoelectric actuator (2), and a control valve (14) that is actuatable by the booster. A device (27) for temperature compensation of a change in length of the piezoelectric actuator (2) dictated by a change in temperature is also provided. The booster is embodied as a diaphragm (3) and is disposed in a prestressed state. The diaphragm (3) boosts the stroke of the piezoelectric actuator with a boosting ratio a/b. At the same time, sealing off of the piezoelectric actuator (2) from the fluid to be controlled is furnished by the diaphragm (3).

### PRIOR ART

The present invention relates to a valve for controlling fluids and in particular to a fuel injection valve.

Valves for controlling fluids are known in various embodiments. For instance from U.S. Pat. No. 4,022,166, a piezoelectric fuel injection valve is known in which the control of the valve member is effected via a piezoelectric element. The stroke of the piezoelectric element is transmitted directly to the valve needle via a lever. Two restoring springs are also provided, in order to keep the valve needle and the lever each in their outset position. This design with two restoring springs which are connected to one another via the lever results in a structure which is very vulnerable to oscillation, and which in particular is unsuited to high-pressure injection, because the oscillations can add up.

Injectors are also known that use hydraulic boosters to boost the stroke of a piezoelectric actuator. However, such versions generally have a relatively complicated construction and comprise many parts. In addition, constant filling of the hydraulic booster is necessary if leakage losses are to be compensated for; this makes such valves relatively complicated and increases the production costs.

Since the piezoelectric actuators have only a very small stroke capacity that has to be boosted, the expense for the known mechanical or hydraulic boosters is relatively high.

### ADVANTAGES OF THE INVENTION

The valve for controlling fluids of the invention having the characteristics of claim 1 has the advantage over the prior art that it has only a small number of parts and is as a result very simply constructed and can be produced economically. According to the invention, for boosting the stroke of a piezoelectric actuator, a diaphragm booster is used. When a diaphragm is used for mechanically boosting the stroke of the piezoelectric actuator, it is possible in particular to dispense with the levers otherwise needed, which have to be produced with high precision and typically account for a very large share of the production costs for mechanical boosters. By comparison, the diaphragm can be furnished quite economically. Moreover, the diaphragm of the invention is prestressed and furnishes a sealing function. As a result, in the boosting according to the invention, sealing off from leak fuel is achieved. Moreover, a device for temperature compensation is also provided, to compensate for a change in length of the piezoelectric actuator upon increases in temperature during operation. By the inventive combination of the temperature compensation with a prestressed diaphragm booster, a stroke of the piezoelectric actuator can be boosted with high precision and without a time lag, and because the valve has only a small number of components, it is quite compact. Hence only a small amount of installation space is needed for the valve of the invention.

The diaphragm is preferably prestressed by means of a spring element. Especially preferably, a cup spring or a spiral spring is used.

The diaphragm is especially preferably prestressed toward the piezoelectric actuator. As a result, prestressing of the piezoelectric actuator is simultaneously made possible. Thus a separate prestressing element for the piezoelectric actuator can be omitted.

In a preferred embodiment of the present invention, the diaphragm is embodied such that it has an annular force introduction region that protrudes toward the piezoelectric actuator. Preferably, a force outputting region is then embodied in the interior of the force introduction region.

Especially preferably, for prestressing the diaphragm, the spring element engages the underside of the force introduction region. As a result, the prestressing force of the spring element can act directly on the piezoelectric actuator. To protect the diaphragm against damage, intermediate elements are preferably provided between the contact regions of the diaphragm and the prestressing element, or components of the piezoelectric actuator.

The diaphragm of the invention is preferably disposed such that it seals off the piezoelectric actuator from the control valve. The booster diaphragm is thus simultaneously embodied as a sealing element as well. In contrast, in the known mechanical and hydraulic boosters, an additional seal is needed to seal off the piezoelectric actuator from the fluid to be controlled. A separate seal is typically used directly at the piezoelectric actuator for this purpose. By means of the embodiment according to the invention, the diaphragm thus has a dual function of boosting the piezoelectric actuator stroke and sealing off the piezoelectric actuator. As a result, in particular, the number of parts can be reduced further and production costs can be lowered.

The device for temperature compensation is advantageously disposed directly on the piezoelectric actuator. As a result, an especially compact structure of the valve of the invention can be achieved.

In an especially preferred feature of the present invention, the device for temperature compensation includes a first base part, a second base part, and a sleeve. The first and second base parts are disposed on the face ends of the piezoelectric actuator. The sleeve surrounds the base parts and the piezoelectric actuator. The temperature-dictated change in length of the first and second base parts and of the piezoelectric actuator is essentially equivalent to the temperature-dictated change in length of the sleeve. The piezoelectric actuator is especially preferably surrounded by a heat-conducting medium.

Furthermore, the sleeve preferably comprises a material, such as Invar, that has a coefficient of expansion similar to the piezoelectric actuator. The base parts can for instance be made from aluminum, in order to optimize the temperature compensation. The piezoelectric actuator in general has a negative coefficient of expansion, and the aluminum base parts have a positive coefficient of expansion, so that the total expansion is approximately equivalent to the expansion of the sleeve.

In order to have the smallest possible number of components, the diaphragm is in direct contact with the second base part of the temperature compensation device.

To minimize the tensile stresses on the diaphragm, the diaphragm is preferably bent, at its fastening on the side, at a predetermined angle counter to the force direction of the piezoelectric actuator.

Also according to the invention, a predetermined spacing may exist between the diaphragm and the second base part, in the unactuated state of the valve. As a result, any temperature-dictated changes in length of the components that may still occur can then be compensated for, and thus any residual error of the temperature compensation that may still be present can be compensated for. It should be noted that it is also possible to provide a spacing between the diaphragm and a valve member of the control valve. However, it is preferable to provide the spacing for temperature compensation between the diaphragm and the second base part, because as a result the error in the temperature compensation will not be boosted as well by the diaphragm booster.

Preferably, the control valve is embodied as an outward-opening valve.

Especially preferably, the valve of the invention is used as a fuel injection valve in a reservoir-type injection system, such as a common rail system.

### DRAWINGS

One exemplary embodiment of the drawing is explained in further detail in the ensuing description. Shown are:

FIG. 1, a schematic sectional view of a valve for injecting fuel, in an exemplary embodiment of the present invention, and

FIG. 2, a schematic enlarged fragmentary view of the diaphragm shown in FIG. 1.

### DESCRIPTION OF THE EXEMPLARY EMBODIMENT

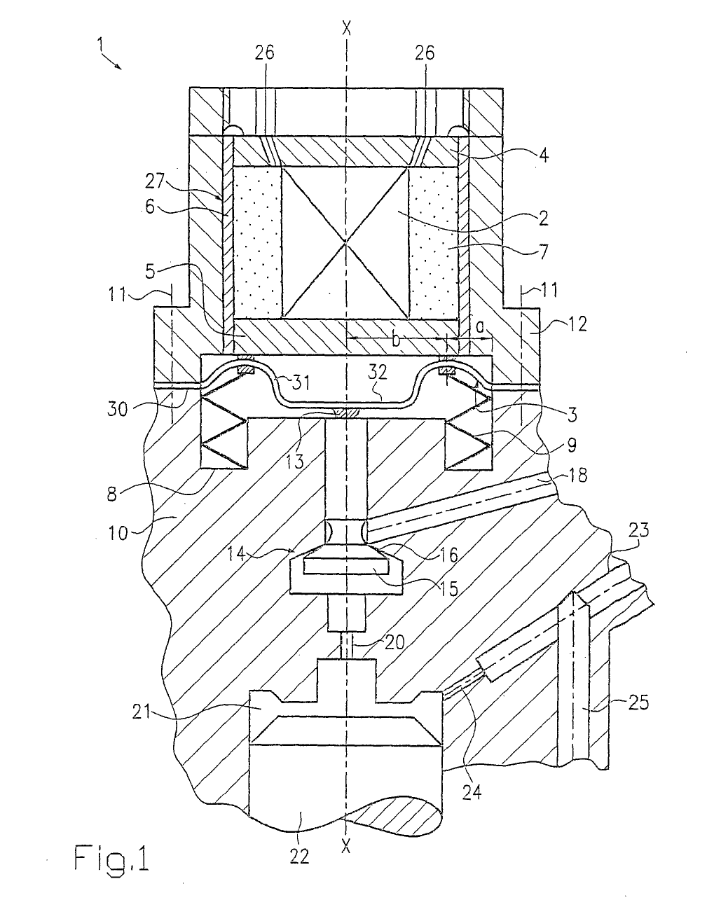

FIG. 1 shows a sectional view of a fuel injection valve 1 for a common rail system, in accordance with the present invention.

As shown in FIG. 1, the valve 1 includes a piezoelectric actuator 2, a device 27 for temperature compensation, and a prestressing element 9. The temperature compensation device 27 includes a first base part 4, a second base part 5, a sleeve 6, and a heat-conducting medium 7. The first and second base parts 4 and 5 are each disposed on respective face ends of the piezoelectric actuator 2. The heat-conducting medium 7 surrounds the side regions of the piezoelectric actuator 2. The sleeve 6 acts as a housing and surrounds both the two base parts 4 and 5 and the heat-conducting medium 7. The base parts 4 and 5 are made from aluminum, and the sleeve 6 is made from Invar, which has a coefficient of expansion similar to that of the piezoelectric actuator. The piezoelectric actuator 2 has a negative coefficient of expansion, and the aluminum base parts have a high positive coefficient of expansion, so that the total is approximately equal to the expansion of the sleeve 6. Through bores are also provided in the first base part 4, so that lines for electrical connections 26 can be passed through them.

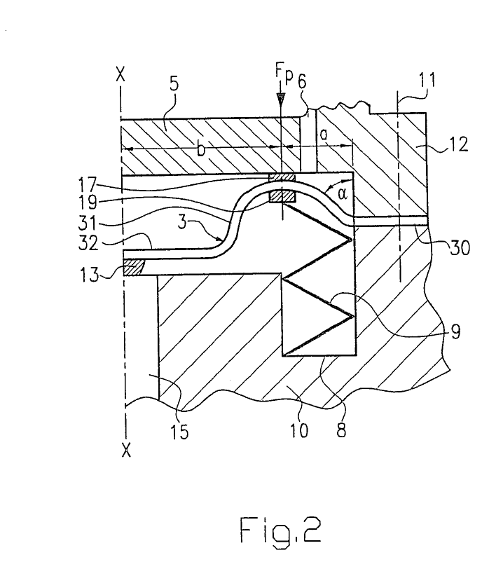

In FIG. 2, the diaphragm 3 of the invention is shown enlarged. The diaphragm 3 includes a retaining region 30, a force introduction region 31, and a fuel output region 32. At the retaining region 30, which is equivalent to the peripheral region of the diaphragm 3, the diaphragm 3 is firmly fastened in place between a housing shoulder 12 and an injector holder body 10. The fastening is done by means of a screw fastening 11, which passes through the diaphragm 3.

The force introduction region 31 of the diaphragm is formed in beadlike fashion and is bent counter to the force direction F_{P} of the piezoelectric actuator (see FIG. 2). The force introduction region 31 projects from the diaphragm 3 toward the piezoelectric actuator 2. The force introduction region 31 is in direct contact with the second base part S. For protecting the diaphragm 3, intermediate elements 17 and 19 are disposed at the contact points between the diaphragm and the second base part 5, and between the diaphragm and the spring element 9. The fuel output region 32 is embodied as a flat and circular and rests in the middle of the annular force introduction region 31. At the fuel output region 32, the stroke of the piezoelectric actuator 2, boosted by the diaphragm 3, is output to a control valve 14. More precisely, the stroke is output to a valve member 15, which is in communication with the diaphragm via a pressure element 13 for protecting the diaphragm 3 (see FIG. 1).

The control valve 14 includes the valve member 15 and opens and closes a valve seat 16. The valve member 15 comprises a cylindrical region with an annular groove and a stopper region with slanted contact faces. In the outset position, the valve member 15 is on the valve seat 16 and closes it. Via the annular groove in the valve member 15, the control valve 14 continues to communicate with a leak fuel line 18, which leads to a leak fuel connection (see FIG. 1).

Via a throttle 20, a the control valve 14 also communicates with a control chamber 21, in which a piston 22 is disposed. Via the piston 22, a valve needle, not shown, is actuated in a known manner. Via a throttle 24, the control chamber 21 is in communication with an inlet 23 from the common rail. A line 25 branching off from the inlet 23 leads to the nozzle.

As shown in FIG. 1, the spring element 9 is embodied as an annular cup spring, which is disposed in a recess 8 made in the injector holder body 10. The spring element 9 prestresses the diaphragm in the direction of the piezoelectric actuator 2. At the same time, the piezoelectric actuator 2 itself is also prestressed by the spring element 9.

The mode of operation of the valve 1 of the invention will be described below.

When the piezoelectric actuator 2 is activated, its stroke is transmitted to the diaphragm 3 via the second base part 5. More precisely, the stroke of the piezoelectric actuator 2 is transmitted to the force introduction region 31 of the diaphragm 3. The diaphragm 3 at this time is firmly fastened between the threaded ring 11 and the housing shoulder 12. An O-ring can be provided on the outer circumference of the diaphragm 3, for sealing off the fastened region.

As shown in FIG. 2, the force introduction region 31 of the diaphragm 3 is disposed at an angle α to the retaining region 30. At a transitional region between the retaining region 30 and the force introduction region 31, a curved region with a predetermined radius is also provided. Because of this embodiment at the fastening point of the diaphragm 3, the tensile stresses in the diaphragm can be minimized. This assures a long service life for the diaphragm 3.

The force F_{P} exerted on the diaphragm 3 by the piezoelectric actuator 2 is boosted by the diaphragm boosting ratio a/b and in the fuel output region 32 is transmitted to the control valve 14 via the pressure element 13. The distance a here is equivalent to the spacing between the center of the introduced force F_{P} of the piezoelectric actuator 2 and the inner peripheral region of the fastened diaphragm 3. The distance b corresponds to the spacing from the center of the introduced F_{P} to the center axis X-X of valve 1 (see FIG. 2). Because of the prestressing of the diaphragm 3 by means of the spring element 9, high tensile strains occur on the underside at the fastening point 30 of the diaphragm 3, that is, on the side toward the control valve 14, while high compressive strains occur at the top, that is, on the side oriented toward the piezoelectric actuator 2, but these are limited because of the aforementioned curved embodiment with a predetermined radius. During the motion of the diaphragm, these stresses are reduced.

The boosted stroke of the piezoelectric actuator 2 is transmitted to the valve member 15 of the control valve 14, which as a result lifts from its valve seat 16. This creates a communication between the control chamber 21 and the leak fuel line 18, so that the pressure in the control chamber 21 drops. As a result, the piston 22 is moved upward in the direction of the piezoelectric actuator 2, and a valve needle (not shown) connected to the piston 22 lifts from its seat. As a result, the fuel injection at the valve needle begins.

When the injection is then to be ended, the piezoelectric actuator 2 is triggered once again, and as a result it returns to its outset position. The return to its outset position is reinforced by the spring element 9. The spring element 9 also assures that the diaphragm 3 returns to its outset position as well, so that the valve member 15 again rests on the valve seat 16 and closes the opening. As a result, a pressure can build up again in the control chamber 21, as a result of which the piston 22 is moved downward again into its outset position. Thus the valve needle connected to the piston 22 closes the injection opening again, so that the injection of fuel is concluded.

According to the invention, during operation of the valve the temperature compensation device 27 assures that a change in length of the piezoelectric actuator 2 caused by a temperature increase can be compensated for mechanically. To compensate for a change in length of the piezoelectric actuator 2 that may possibly not be compensated for by the temperature compensation device 27, a predetermined spacing can be provided between the diaphragm 3 and the second base part 5, which spacing is very much less than the stroke of the piezoelectric actuator. This spacing can compensate for any change in length of the piezoelectric actuator 2 that is not compensated for by the temperature compensation device 27.

With the diaphragm 3 of the invention, the stroke of the piezoelectric actuator 2 is thus boosted with a boosting ratio a/b. Depending on the embodiment of the diaphragm and in particular of the force introduction region 31, the boosting ratio can be varied in a relatively simple way.

Besides the function of boosting the piezoelectric actuator stroke, the diaphragm 3 of the invention also takes on a function of sealing the piezoelectric actuator off from the fuel region of the valve. This assures that no fuel can reach the piezoelectric actuator 2, where it could impair the function thereof. Thus the sealing element otherwise required when piezoelectric actuators are used and typically disposed directly on the piezoelectric actuator 2 can be dispensed with. As a result, the production costs for the valve of the invention can be reduced still further.

Since the diaphragm 3 is bent at an angle α counter to the force direction F_{P} of the piezoelectric actuator 2, the tensile stresses in the region where the diaphragm is fastened can be minimized, even though the diaphragm 3 is prestressed in the direction of the piezoelectric actuator 2 by the spring element 9. The angle α is the angle between the horizontal retaining region 30 of the diaphragm and the slope of the force introduction region 31, as shown in FIG. 2.

The present invention thus relates to a valve for controlling fluids having a piezoelectric actuator 2, a booster for boosting the stroke of the piezoelectric actuator 2, and a control valve 14 that can be actuated by the booster. A device 27 for temperature compensation of a change in length of the piezoelectric actuator 2 causes by a change in temperature is also provided. The booster is embodied as a diaphragm 3 and disposed in a prestressed state. The diaphragm 3 boosts the stroke of the piezoelectric actuator with a boosting ratio a/b. At the same time, sealing off of the piezoelectric actuator 2 from the fluid to be controlled is furnished by the diaphragm 3.

The above description of the exemplary embodiment of the present invention is intended solely for purposes of illustration and is not intended to limit the invention. Within the scope of the invention, various changes and modifications can be made without departing from the scope of the invention or its equivalents.

1. A valve for controlling fluids, having a piezoelectric actuator (2), a booster for boosting the stroke of the piezoelectric actuator (2), a control valve (14) actuatable by the booster, and a device (27) for temperature compensation, wherein the booster is embodied as a diaphragm (3), and the diaphragm (3) is prestressed.

2. The valve of claim 1, characterized in that the diaphragm is prestressed by means of a spring element (9), in particular a cup spring or a spiral spring.

3. The valve of claim 1 or 2, characterized in that the diaphragm (3) is prestressed toward the piezoelectric actuator (2).

4. The valve of one of claims 1-3, characterized in that the diaphragm (3) has an annular force introduction region (31), which protrudes toward the piezoelectric actuator (2).

5. The valve of claim 4, characterized in that the spring element (9) engages the underside of the force introduction region (31).

6. The valve of one of claims 1-5, characterized in that the diaphragm (3) seals the piezoelectric actuator (2) off from the control valve (14).

7. The valve of one of claims 1-6, characterized in that the device (27) for temperature compensation is provided directly on the piezoelectric actuator (2).

8. The valve of claim 7, characterized in that the device (27) for temperature compensation includes a first base part (4), a second base part (5), and a sleeve (6), and the first base part (4) and the second base part (5) are each disposed on the face end of the piezoelectric actuator (2), and the sleeve (6) surrounds the base parts (4, 5) and the piezoelectric actuator (2), wherein the temperature-dictated change in length of the first and second base parts (4, 5) and of the piezoelectric actuator (2) is essentially equivalent to the temperature-dictated change in length of the sleeve (6).

9. The valve of claim 8, characterized in that the diaphragm (3) is located in direct contact with the second base part (5).

10. The valve of one of claims 4-9, characterized in that the force introduction region (31) of the diaphragm (3) is bent at an angle (α) relative to the retaining region (30), counter to the force direction force direction (F_{P}) of the piezoelectric actuator (2).
